(19) United States
(12) Patent Application Publication
(10) Pub. No.: US 2018/0197868 A1
(43) Pub. Date: Jul. 12, 2018

(54) SEMICONDUCTOR DEVICE AND MANUFACTURING METHOD THEREOF

(71) Applicants: UNITED MICROELECTRONICS CORP., Hsin-Chu City (TW); Fujian Jinhua Integrated Circuit Co., Ltd., Quanzhou City (CN)

(72) Inventors: Ger-Pin Lin, Tainan City (TW); Tien-Chen Chan, Tainan City (TW); Shu-Yen Chan, Changhua County (TW); Yung-Ming Wang, Taichung City (TW); Chien-Ting Ho, Taichung City (TW)

(21) Appl. No.: 15/866,482

(22) Filed: Jan. 10, 2018

(30) Foreign Application Priority Data
Jan. 11, 2017 (CN) 201710019383.0

(51) Int. Cl. H01L 27/108; H01L 21/76; H01L 21/02; H01L 21/3115

(52) U.S. Cl. CPC H01L 27/10891; H01L 21/31155; H01L 21/02164; H01L 21/76

(57) ABSTRACT

A semiconductor device and a manufacturing method thereof include providing a substrate including an active region of a conductivity type and an isolation structure, in which the isolation structure surrounds the active region; forming a word line trench on the substrate, the word line trench intersecting the active region; and forming two doped regions in the active region at two sides of the word line trench respectively, in which each doped region and a bottom surface of the word line trench are located in a same level, and each doped region includes dopants of the conductivity type or an intrinsic semiconductor dopants.

### BACKGROUND OF THE INVENTION

### 1. Field of the Invention

The present invention relates to a semiconductor device and a manufacturing method thereof, and more particularly to a semiconductor device and a manufacturing method thereof for mitigating a row hammer effect.

### 2. Description of the Prior Art

Generally, dynamic random access memory (DRAM) unit formed of a transistor and a capacitor can store electric charges through the capacitor, so that required data can be recorded. As applications of the DRAM increase, size of the DRAM is to be continuously downsized to improve integrality of the DRAM, operating speed of device, and capacity of the DRAM and meet the consumer requirement to miniaturization of the electronic device.

However, when the size of memory is smaller, density of word lines used as gate is higher, which results in a row hammer issue. That is to say, since there are defects between silicon substrate and oxide layer that would capture electric charges, these captured electric charges would easily become leakage current crossing adjacent word lines when the memory is repeatedly read and write, thereby resulting in data errors of the memory cell. Especially, an active region near a word line in an insulation structure is near a storage node, so the electric charges are more easily accumulated in the defects between the active region and the insulation structure. Accordingly, these captured electric charges cross the adjacent word lines to flow into a bit line when repeatedly reading and writing, thereby generating data errors.

### SUMMARY OF THE INVENTION

It is therefore one of objectives of the present invention to provide a semiconductor device and a manufacturing method thereof in order to prevent the row hammer effect and reduce data errors.

An embodiment of the present invention provides a semiconductor device including a substrate, two first doped regions, a word line structure, and two source/drain regions. The substrate includes an active region, an isolation structure and a word line trench, in which the isolation structure surrounds the active region, the word line trench penetrates through the active region, and the active region has a first conductivity type complementary to a second conductivity type. The first doped regions are disposed in the active region and respectively at two sides of the word line trench, each first doped region and a bottom surface of the word line trench are located at a same level, and each first doped region comprises dopants of the first conductivity type or intrinsic semiconductor dopants. The word line structure is disposed in the word line trench. The source/drain regions are disposed in the active region and respectively on the first doped regions at the two sides of the word line trench, in which the source/drain regions have the second conductivity type.

An embodiment of the present invention provides a manufacturing method of a semiconductor device. First, a substrate is provided. The substrate includes an active region and an isolation structure, the isolation structure surrounds the active region, and the active region has a first conductivity type complementary to a second conductivity type. Then, a word line trench penetrating the active region is formed on the substrate. Thereafter, two first doped regions are formed in the active region and respectively at two side of the word line trench. Each first doped region and a bottom surface of the word line trench are located at a same level, and each first doped region includes dopants of the first conductivity type or intrinsic semiconductor dopants.

In the semiconductor device of the present invention, through forming the first doped region including dopants of the first conductivity type or intrinsic semiconductor dopants in the active region under each source/drain region, the ability of the carriers of the second conductivity type penetrating through the first doped regions can be reduced, and the carriers of the second conductivity type limited in the defects between the active regions and the isolation structure can be lowered to flow to the bit lines or other storage nodes, so as to mitigate the occurrence of the row hammer effect.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 6, which are schematic diagrams illustrating a manufacturing method of a semiconductor device.

FIG. 7 is a schematic diagram illustrating a manufacturing method of a semiconductor device according to a second embodiment of the present invention.

### DETAILED DESCRIPTION

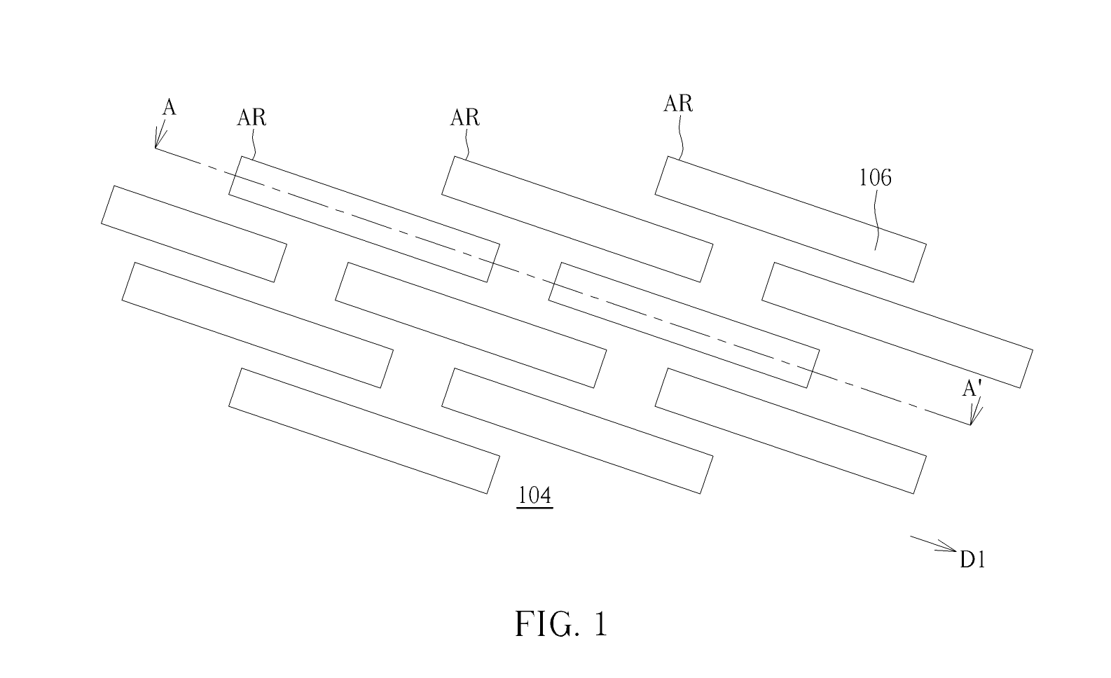

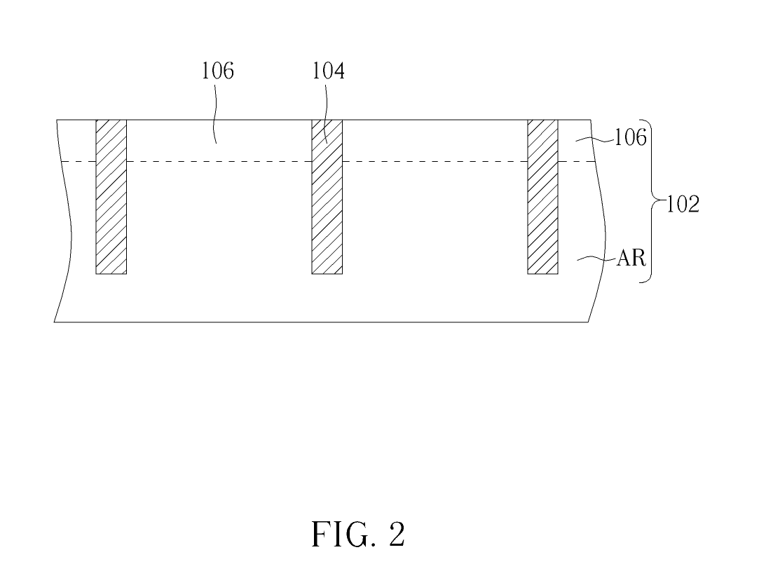

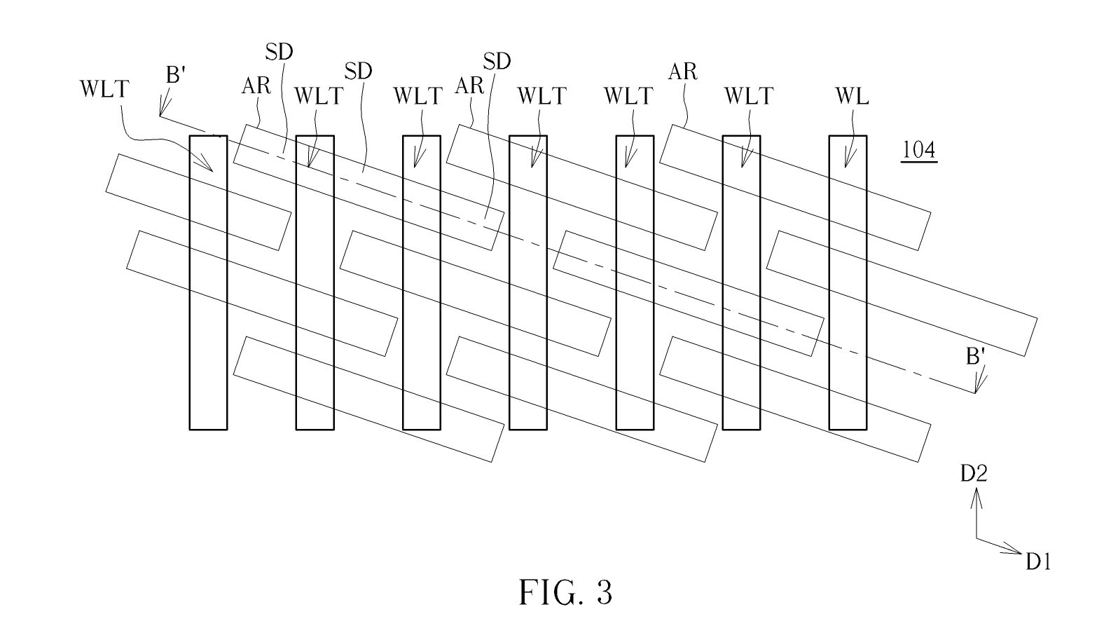

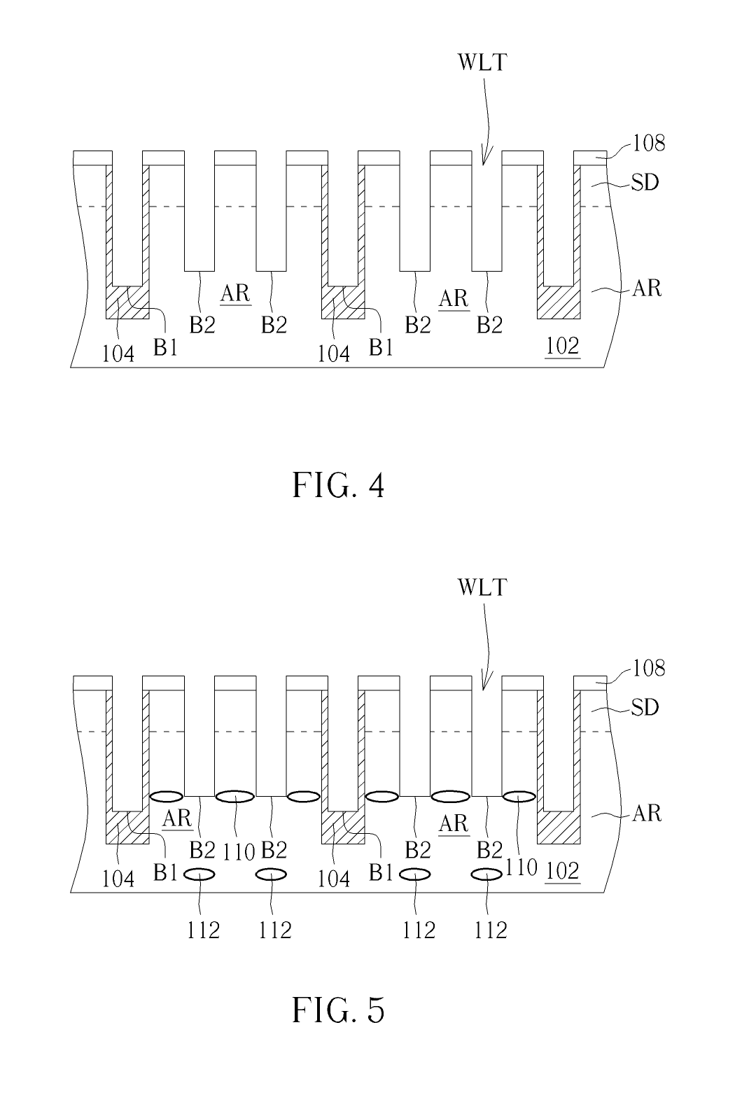

Refer to FIG. 1 to FIG. 6, which are schematic diagrams illustrating a manufacturing method of a semiconductor device, wherein FIG. 2 is a cross-sectional view taken along a line A-A′ of FIG. 1, and FIG. 4 is a cross-sectional view taken along a line B-B′ of FIG. 3. First, as shown in FIG. 1, a substrate is provided. In this embodiment, the substrate 102 may include one or more active regions AR parallel to each other, and each active region AR may be a strip structure extending along a direction D1. Specifically, the semiconductor device 100 may include an isolation structure 104 disposed in the substrate 102, and the isolation structure 104 surrounds each active region AR to define the active regions AR and electrically isolate the active regions AR. A top surface of the isolation structure 104 and a top surface of the substrate 102 may be located at a same level. An n-type metal-oxide-semiconductor (NMOS) transistor to be formed is taken as an example, the active regions AR may have a first conductivity type, such as p type, and a doping concentration of each active region AR may be adjusted to be a doping concentration of a required channel region of the transistor to be formed before or after forming the isolation structure 104. In this embodiment, after adjusting the doping concentration of each active region AR, each active region AR may have a third doped region 106 formed on top thereof. The third doped region 106 has a second conductivity type, such as n type, but not limited thereto. In another embodiment, if a p-type metal-oxide-semiconductor (PMOS) is to be formed, the first conductivity type may be n type, and the second conductivity type may be p type. Additionally, the substrate 102 may include a silicon substrate, a silicon-containing substrate, a III-V semiconductor-on-silicon (such as GaAs-on-silicon) substrate, a graphene-on-substrate, or a silicon-on-insulator (SOI) substrate.

Then, as shown in FIG. 3 and FIG. 4, one or more word line trenches WLT are formed on the substrate 102, in which the word line trenches WLT penetrate through each active region AR and the isolation structure 104, so that the third doped region 106 in each active region AR may be separated into two source/drain regions SD. Specifically, a protection layer 108, such as silicon oxide, is formed on the substrate 102 and the isolation structure 104 and followed by performing a photolithography process to form a photoresist pattern exposing position of the word line trenches WLT. After that, the protection layer 108 and the substrate 102 are etched by an etching process to form a plurality of word line trenches WLT parallel to each other, in which the word line trenches WLT extend along the direction D2 respectively, and a depth of each word line trench WLT is less than a depth of the isolation structure 104. Each active region AR may be penetrated through by two adjacent word line trenches WLT, and a depth of the third doped region 106 is less than the depth of each word line trench WLT, such that the third doped region 106 of each active region AR may be divided into three source/drain regions SD of the second conductivity type. In this embodiment, the isolation structure 104 may be formed of oxide. Since the etching process has faster etching rate to the oxide than silicon, a portion of each word line trench WLT in the isolation structure 104 may be deeper than a portion of each word line trench WLT in the active regions AR. In other words, each word line trench WLT may have first bottom surfaces B1 in the isolation structure 104 and second bottom surfaces B2 in the active regions AR. For example, a spacing between each first bottom surface B1 of each word line trench WLT in the isolation structure 104 and a top surface of each active region AR may be substantially 1800 angstroms, and a spacing between each second bottom surface B2 of each word line trench WLT in each active region AR and the top surface of each active region AR may be substantially 1500 angstroms, but the present invention is not limited thereto.

Subsequently, as shown in FIG. 5, two first doped regions 110 are formed in the active region AR and respectively at two sides of each word line trench WLT, and the first doped regions 110 and the first bottom surfaces B1 may be located at a same level, the first doped regions 110 and the second bottom surfaces B2 may be located at the same level, or the first doped regions 110 are located between a level of each first bottom surface B1 and a level of each second bottom surface B2. Preferably, the first doped regions 110 and the second bottom surfaces B2 are located at the same level. The term “level” as used herein is defined as a plane parallel to the substrate 102, and its extending direction may be disregarded without significantly affecting. Specifically, the first doped regions 110 and the second bottom surfaces B2 located at the same level are taken as an example, an ion implantation process with a certain implant energy is performed, such that dopants can penetrate through the protection layer 108 and a part of the active region AR, and be implanted into the active regions AR located at the same level as the second bottom surfaces B2 of the word line trenches WLT. For example, the dopants are implanted into the active regions AR with a spacing of substantially 1500 angstroms spaced apart from the top surface of each active region AR. The implant energy of the ion implantation process may be for example ranged from about 550 keV to about 600 keV, and implant concentration may be for example about 8E12 cm−2. After that, an annealing process is performed to form the first doped regions 110. The first doped regions 110 are located in the active regions AR and at the same level as the second bottom surfaces B2, so the first doped regions 110 are located under the source/drain regions SD respectively. Also, since duration of the annealing process is short, for example 30 seconds, each first doped region 110 would not be diffused to be in contact with the source/drain region SD disposed above it, and the formation of each first doped region 110 would not significantly affect operation of the channel region of the transistor. Temperature of the annealing process may be for example about 1050° C.

In this embodiment, the dopants are not the second conductivity type, so that carrier concentration of the second conductivity type complementary to the first conductivity type of each first doped region 110 may be less than carrier concentration of the second conductivity type of each active region AR, thereby reducing ability of carriers of the second conductivity type to penetrate through the first doped regions 110. For example, the dopants may be the first conductivity type, and when the first conductivity type is p type, the dopants may be for example boron, aluminum, gallium or indium. When the first conductivity type is n type, the dopants may be for example phosphorous, arsenic or antimony. Since each first doped region 110 includes the dopants of the first conductivity type, the doping concentration of each first doped region 110 may be greater than the doping concentration of each active region AR. In another embodiment, the dopants included in each first doped region 110 may be intrinsic semiconductor dopants, such as carbon, silicon or germanium. Although the doping concentration of each first doped region 110 of the first conductivity type formed by the intrinsic semiconductor dopants is less than the doping concentration of each active region AR of the first conductivity type, the intrinsic semiconductor dopants can reduce ability of the carriers of the second conductivity type to penetrate through the first doped regions 110.

While forming the first doped regions 110, the word line trenches WLT are not filled with any materials, so the ion implantation process may also form a second doped region 112 in the substrate 102 under each word line trench WLT at the same time as forming the first doped regions 110. Accordingly, an area formed by the first doped regions 110 and the second doped region 112 corresponding to the same active region AR in a vertical projection direction Z is the same as an area of the corresponding active region AR. The vertical projection direction Z is defined to be perpendicular to the level defined as mentioned above. Since the first doped regions 110 and the second doped regions 112 are formed by the same ion implantation process and the same annealing process, each second doped region 112 and each first doped region 110 include the same dopants of the first conductivity type, and the spacing between each second doped region 112 and each second bottom surface B2 of each word line trench WLT may be substantially the same as the spacing between each first doped region and the top surface of the protection layer 108. For example, the level of the bottom surface of the isolation structure 104 may be between each second doped region 112 and each first doped region 110. In another embodiment, each second doped region 112 may include intrinsic semiconductor dopants.

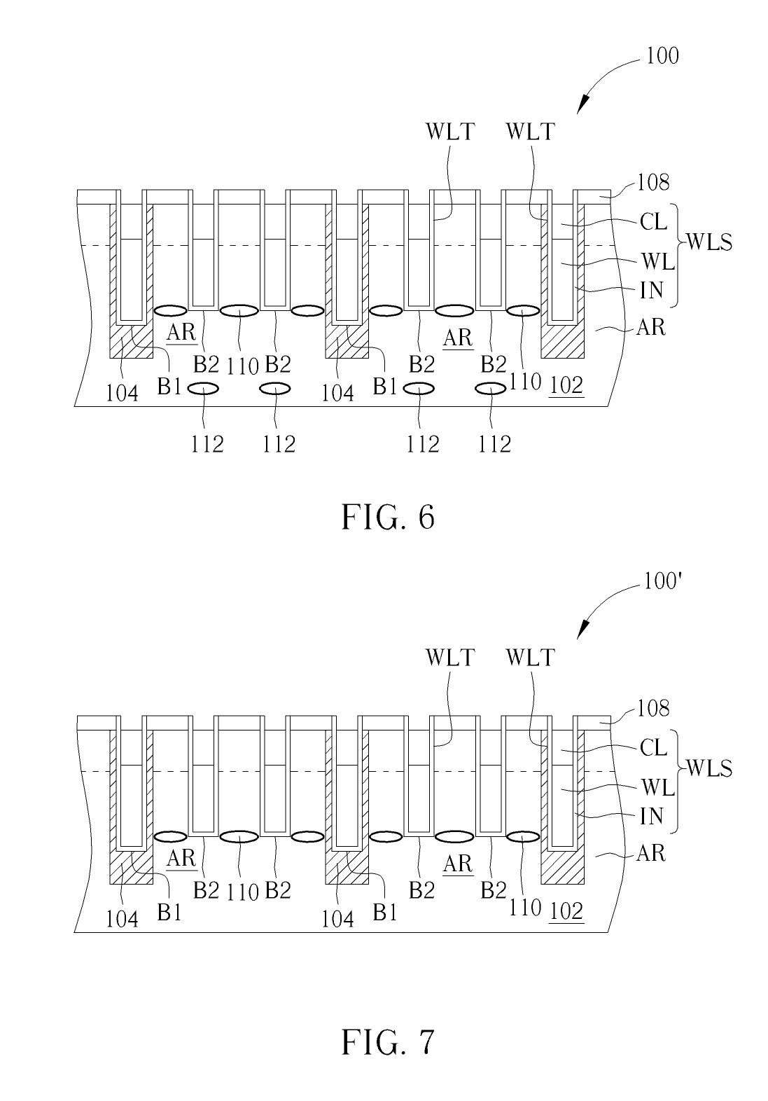

Thereafter, as shown in FIG. 6, a word line structure WLS is formed in each word line trench WLT respectively, and the semiconductor device 100 of this embodiment is accordingly formed. Specifically, each word line structure WLS may include an insulation layer IN, a word line WL, and a cap layer CL, the insulation layer IN is disposed between the word line WL and the substrate 102 for serving as a gate insulation layer, and the cap layer CL is disposed on the word line WL for protecting the word line WL. It will be apparent to one skilled in the art that after forming the word line structures WLS, structures of bit lines and capacitors may be formed on the substrate to form the semiconductor device 100 with DRAM and will not be further detailed herein.

It should be noted that in the semiconductor device 100 of this embodiment, since each first doped region 110 is formed in the active region AR under each source/drain region SD and includes dopants of not second conductivity type, the carrier concentration of the second conductivity type of each first doped region 110 can be less than the carrier concentration of the second conductivity type of each active region AR. By doing so, the ability of the carriers of the second conductivity type to penetrate through the first doped regions 110 can be reduced, and the carriers of the second conductivity type limited in the defects between the active regions AR and the isolation structure 104 can be lowered to flow to the bit lines or other storage nodes, so as to mitigate the occurrence of the row hammer effect.

In another embodiment, before forming the word line trenches WLT, each active region AR may have no third doped region formed therein, so the source/drain regions SD are not formed before forming the word line structures WLS, and the source/drain regions SD are formed in the active regions AR and respectively on the first doped regions 110 at two sides of the word line trenches WLT by another ion implantation process and another annealing process after the word line structures WLS are formed.

The semiconductor device and the manufacturing method thereof of the present invention are not limited to the above-mentioned embodiment. The following description continues to detail the other embodiments, and in order to simplify and show the difference between the other embodiments and the above-mentioned embodiment, the same numerals denote the same components in the following description, and the same parts are not detailed redundantly.

Refer to FIG. 7 as well as FIG. 1 to FIG. 4. FIG. 7 is a schematic diagram illustrating a manufacturing method of a semiconductor device according to a second embodiment of the present invention. The difference between this embodiment and the first embodiment is that the first doped regions 110 are formed after the word line structures WLS are formed in this embodiment, so the semiconductor device 100′ of this embodiment doesn't have the second doped regions. Specifically, the step for forming the word line trenches WLT and the steps before it in this embodiment are the same as the first embodiment, as shown in FIG. 1 to FIG. 4, and will not further be detailed. After that, as shown in FIG. 7, the word line structures WLS are formed in the word line trenches WLT respectively and followed by performing an ion implantation process and an annealing process to form the first doped regions 110 at the same level as the first bottom surfaces B1, at the same level as the second bottom surfaces B2 or between the level of each first bottom surface B1 and the level of each second bottom surface B2. Accordingly, the semiconductor device 100′ of this embodiment is formed. Since the formed cap layer CL in each word line structure WLS may be formed of a material for blocking ions, such as silicon nitride, no second doped region is formed in the substrate 102, and the cap layer CL may effectively prevent the dopants for forming the first doped regions 110 from affecting electrical characteristic of the word lines WL. The step of forming the source/drain region SD of this embodiment may utilize the method of the first embodiment that is to form the source/drain region SD by dividing the third doped region 106 through the word line trench WLT or to form the source/drain regions SD after the word line structures WLS are formed. When the source/drain regions SD are formed after the word line structures WLS are formed, the source/drain regions SD may be formed before or after the first doped regions 110 are formed.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate comprising an active region, an isolation structure and a word line trench, wherein the isolation structure surrounds the active region, the word line trench penetrates through the active region, and the active region has a first conductivity type complementary to a second conductivity type;
two first doped regions disposed in the active region and respectively at two sides of the word line trench, wherein each first doped region and a bottom surface of the word line trench are located at a same level, and each first doped region comprises dopants of the first conductivity type or intrinsic semiconductor dopants;
a word line structure disposed in the word line trench; and
two source/drain regions disposed in the active region and respectively on the first doped regions at the two sides of the word line trench, wherein the source/drain regions have the second conductivity type.

2. The semiconductor device according to claim 1, further comprising a second doped region disposed in the substrate under the word line trench, and the second doped region comprising dopants of the first conductivity type or intrinsic semiconductor dopants.

3. The semiconductor device according to claim 2, wherein a level of a bottom surface of the isolation structure is between the second doped region and each first doped region.

4. The semiconductor device according to claim 2, wherein an area formed by the first doped regions and the second doped region in a vertical projection direction is the same as an area of the active region.

5. The semiconductor device according to claim 1, wherein each first doped region comprises the dopants of the first conductivity type, and a doping concentration of each first doped region is greater than a doping concentration of the active region.

6. The semiconductor device according to claim 1, wherein a depth of the word line trench is less than a depth of the isolation structure.

7. A manufacturing method of a semiconductor device, comprising:
providing a substrate, wherein the substrate comprises an active region and an isolation structure, the isolation structure surrounds the active region, and the active region has a first conductivity type complementary to a second conductivity type;
forming a word line trench penetrating the active region on the substrate; and
forming two first doped regions in the active region and respectively at two side of the word line trench, wherein each first doped region and a bottom surface of the word line trench are located at a same level, and each first doped region comprises dopants of the first conductivity type or intrinsic semiconductor dopants.

8. The manufacturing method of the semiconductor device according to claim 7, further comprising forming a word line structure in the word line trench after forming the first doped regions.

9. The manufacturing method of the semiconductor device according to claim 7, further comprising forming a word line structure between providing the substrate and forming the first doped regions.

10. The manufacturing method of the semiconductor device according to claim 7, wherein the dopants of the first conductivity type comprise boron, aluminum, gallium or indium.

11. The manufacturing method of the semiconductor device according to claim 7, wherein the intrinsic semiconductor dopants comprise carbon, silicon or germanium.

12. The manufacturing method of the semiconductor device according to claim 7, wherein forming the first doped regions further comprises forming a second doped region in the substrate under the word line trench, and wherein a carrier concentration of the second conductivity type of the second doped region is less than a carrier concentration of the second conductivity type of the active region.

13. The manufacturing method of the semiconductor device according to claim 7, further comprising forming a third doped region in the active region before forming the word line trench, and forming the word line trench comprises separating the third doped region into two source/drain regions, wherein each source/drain region has the second conductivity type.

14. The manufacturing method of the semiconductor device according to claim 7, further comprising:
forming a word line structure in the word line trench after forming the word line trench; and
forming two source/drain regions in the active region and respectively on the first doped regions at the two sides of the word line trench, and each source/drain region has the second conductivity type.
